(19) United States
(12) Patent Application Publication
(10) Pub. No.: US 2006/0214205 A1
(43) Pub. Date: Sep. 28, 2006

(54) Thin-film capacitor element and semiconductor device

(75) Inventors: John David Baniecki, Kawasaki (JP); Kenji Nomura, Kawasaki (JP); Takeshi Shioga, Kawasaki (JP); Kazuaki Kurihara, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/349,121

(22) Filed: Feb. 8, 2006

Related U.S. Application Data
(63) Continuation-in-part of application No. 11/168,935, filed on Jun. 29, 2005.

(30) Foreign Application Priority Data
Mar. 28, 2005 (JP) 2005-91845
Nov. 21, 2005 (JP) 2005-335189

(51) Int. Cl. H01L 29/94

(52) U.S. Cl. 257/295

(57) ABSTRACT

To provide a thin-film capacitor and a semiconductor device capable of preventing a reduction in the dielectric constant due to a residual tensile stress in a ferroelectric layer in a thin-film capacitor using the ferroelectric substance, and increasing the dielectric constant and increasing an electric capacity. In a thin-film capacitor 10 having a lower electrode 2, a ferroelectric layer 3, and an upper electrode 4 on a substrate 1, the thin-film capacitor 10 has the upper electrode 4 that adds a compressive stress to the ferroelectric layer 3, and a residual compressive stress in the upper electrode 4 is within a range from 10⁸ to 6×10¹¹ dyne/cm².

### CROSS-REFERENCE TO RELATED APPLICATIONS

This application is based upon and claims the benefit of priority from the prior Japanese Patent Application No. 2005-91845, filed on Mar. 8, 2005, prior Japanese Patent Application No. 200 5-335189, filed on Nov. 21, 2005 and the entire contents of which are incorporated herein by reference.

### BACKGROUND OF THE INVENTION

1. Field of the Invention

The present invention relates to a thin-film capacitor having a capacitor structure formed on a substrate such as a semiconductor substrate by a thin-film manufacturing process, and to a semiconductor device.

2. Description of the Related Art

In recent years, there has been studied the application of a thin-film capacitor made of a high dielectric-constant oxide and a ferroelectric oxide to a charge storage capacitance element for a dynamic random access memory (DRAM) and a ferroelectric random access memory (FRAM), a filter element in a microwave device, and a decoupling element that restricts voltage noise and a voltage variation generated in a power bus line.

In these techniques, a ferroelectric substance is used as a dielectric material of a capacitor. A thin-film capacitor that uses this ferroelectric substance has high capacity in a compact size and is excellent for micro-fabrication. Therefore, the thin-film capacitor can be connected to a circuit substrate as a bump connection having a small pitch between terminals. With this arrangement, mutual inductance can be decreased, and the thin-film capacitor can be effectively connected to a large-scale integration (LSI) in low inductance. Usually, the thin-film capacitor includes a capacitor structure, having a dielectric layer sandwiched between a lower electrode layer and an upper electrode layer, on the substrate. The dielectric substance having this structure has disadvantage in that the dielectric characteristics, such as a dielectric constant and a dielectric loss, decrease as compared with dielectric characteristics of a dielectric substance in a bulk state. For example, while a perovskite oxide (Ba, Sr)TiO₃ (hereinafter, also referred to as “BST”) has a high dielectric constant, this BST has a dielectric constant that exceeds 15,000 near the Curie temperature Tc (308° K. at Ba/Sr=70/30). However, the dielectric constant of a BST thin film that uses platinum (Pt) as upper and lower electrodes on a silicon (Si) substrate decreases to a few hundreds. This becomes a factor that interrupts an actual wide application of the thin-film capacitor made of BST and the like.

This is considered because the actual device such as a thin-film capacitor takes a laminated structure in the ferroelectric thin film, the stress of a few hundred MPa or above is added to the perovskite oxide thin film. Depending on whether this stress is a tensile stress or a compressive stress the dielectric constant of the perovskite oxide thin film is greatly affected. Various mechanisms including lattice inconsistency, thermal expansion inconsistency, and an intrinsic stress at the time of forming a film are considered as causes of the occurrence of the internal stress in the thin film. In the usage of high dielectric-constant and ferroelectric materials, in many cases, it is preferable to deposit these materials on a low-cost substrate such as Si (silicon) and polymer substrates. However, because of a large difference of thermal expansion coefficients between the Si (silicon) and polymer substrates and a titanic acid perovskite dielectric substance such as BST and PZT, a ferroelectric film has a residual tensile stress, after the ferroelectric film is cooled down from a high deposition temperature of 400° C. to 700° C. in general. When the ferroelectric film is deposited at a higher deposition temperature, a residual tensile stress of a few 10⁹ dyne/cm² is generated, thereby decreasing the dielectric constant. However, techniques of increasing the dielectric constant by positively using these stresses in many devices using the ferroelectric substance are reported.

For example, Japanese Patent Application Laid-Open No. 2004-241679 discloses a semiconductor device that includes: a first insulating film formed on a semiconductor substrate; a capacitor lower electrode having a laminated structure of different materials formed on the first insulating film and having a stress of −2×10⁹ to 5×10⁹ dyne/cm²; a dielectric film formed on the capacitor lower electrode; a capacitor upper electrode formed on the dielectric film; and a second insulating film that covers a capacitor including the capacitor lower electrode, the dielectric film, and the capacitor upper electrode. However, in the patent document 1, it is explained that a platinum film as a lower electrode film has a compressive stress to prevent the lower electrode film and the ferroelectric layer from being easily peeled off from a base film or the like, and neither the improvement in the dielectric characteristic of the ferroelectric layer nor the influence of the upper electrode is explained.

Japanese Patent Application Laid-Open No. 2000-277701 discloses a semiconductor element including: a lower electrode; a dielectric film formed on an upper surface of the lower electrode; an upper electrode formed on an upper surface of the dielectric film; and a hetero film formed adjacent to the upper electrode so as to induce a compressive stress from the dielectric film. However, according to this technique, although a hetero film is provided on the upper electrode, this hetero film uses a substance compressed in a heat treating. Therefore, the number of manufacturing steps increases, and this makes the manufacturing complex and decreases productivity.

U.S. Pat. No. 6,514,835 discloses a method of manufacturing a thin firm by extracting a ferroelectric substance on a substrate, thermally treating the ferroelectric substance on the substrate above or near the Curie point, and controlling the stress due to a mechanical deformation of a wafer substrate at a deposition time. However, this has a problem in that a special in situ bending device is necessary in executing the technique in a device manufacturing process. Further, there is a problem in that a temperature of the substrate and a film thickness on the bent wafer are not uniform.

U.S. Pat. No. 5,750,419 discloses a multilayer dielectric structure that is formed on an integrated thin-film capacitor structure including a ferroelectric material. The patent document 4 discloses a manufacturing method capable of preventing degradation of a residual polarization by keeping the tensile force of the dielectric layer at a low level. However, the use of the dielectric layer to add a compressive or tensile stress has a problem in that the dielectric layer cannot be closely adhered to a normal-dielectric or ferroelectric dielectric film.

U.S. Pat. No. 6,342,425 proposes an alternative solution of controlling a tensile state of the dielectric material with a thin-film capacitor. The patent document 5 discloses a method of manufacturing a capacitor for forming a film of a different type near an upper electrode. However, a process to be introduced to only control the tension of a different film and a process of a high-temperature treating to form a silicon compound, that are not necessary in the usual process, become necessary. As a result, productivity of a semiconductor and the like decreases.

### SUMMARY OF THE INVENTION

Therefore, the present invention has been achieved in the light of the above problems. It is an object of the present invention to provide a thin-film capacitor and a semiconductor device capable of preventing a reduction in the dielectric constant due to a residual tensile stress in a ferroelectric layer in a thin-film capacitor using the ferroelectric substance, and increasing the dielectric constant and increasing an electric capacity.

In order to solve the above problems, a thin-film capacitor element according to the present invention has a substrate, and a thin-film capacitor sandwiched between a set of electrode layers having a ferroelectric layer made of a conductive material. An upper electrode out of the electrode layers has a residual compressive stress. The thin-film capacitor element adds a compressive stress to the ferroelectric layer based on this residual compressive stress.

It is known that the internal stress of the perovskite oxide thin film such as BST gives a large influence to the change of dielectric constant. Particularly, in forming a ferroelectric layer, it is known that a tensile stress remains within the ferroelectric substance in many cases. For example, it is known that when a perovskite oxide thin film has a tensile stress of a few 10⁹ dyne/cm² the Curie temperature decreases by a few 10° C. resulting in a reduction of the dielectric constant of the ferroelectric thin film to be measured. The decrease of the Curie temperature that brings about a reduction of the dielectric constant in the normal dielectric state can be understood based on the expression (1) for a temperature dependency of a high dielectric material in the normal dielectric state.
ε=C/(T−Tc) Expression (1)

(where ε represents a dielectric constant, C represents a Curie-Weiss constant, and Tc represents a Curie temperature.)

As is clear from the expression (1), when the inside tensile stress decreases the Curie temperature Tc, the dielectric constant decreases at a temperature above the Curie temperature Tc. On the other hand, the compressive stress of a few 10⁹ dyne/cm² further increases the Curie temperature Tc of a few 10° C., resulting in the increase of the dielectric constant in the normal dielectric state. Therefore, according to the present invention, the thin-film capacitor has such a structure that, in order to compensate for a residual tensile stress, a compressive stress is added to the ferroelectric layer to increase the dielectric constant and the electrostatic capacity of the thin-film capacitor.

Further, the present invention provides a semiconductor device that uses electric characteristics and optical characteristics of the thin-film capacitor that is formed on the semiconductor substrate.

According to the present invention, when an electrode and a ferroelectric are laminated on a substrate made of silicon or the like, the internal stress of this electrode is added to the ferroelectric. With this arrangement, it is possible to provide a thin-film capacitor that can significantly improve the dielectric characteristics such as the dielectric constant and the dielectric loss of the ferroelectric and can increase the electric capacity. Further, it is possible to provide a semiconductor device mounted with this thin-film capacitor.

### BRIEF DESCRIPTION OF THE DRAWINGS

FIG. 1 is a diagram showing a structure of a part of a semiconductor element having a thin-film capacitor according to the present invention.

FIG. 2 is a cross-sectional diagram of a semiconductor device including the thin-film capacitor according to the present invention.

FIG. 3 is a diagram showing a structure of a thin-film capacitor according to a first embodiment of the present invention.

FIG. 4 is a graph showing a result of measuring a relationship between 2θ and sin²_{χ} of the thin-film capacitor according to the present invention based on XRD measurement.

FIG. 5 is a graph showing a C-V curve of the thin-film capacitor according to the first embodiment of the present invention.

FIG. 6 is a diagram showing a structure of a thin-film capacitor according to another embodiment of the present invention.

### DETAILED DESCRIPTIONS

Best modes for carrying out the present invention will be explained below with reference to the accompanying drawings and the like. The description given below is only an example of the embodiments of the present invention, and modifications and variations of the embodiments made within the scope of the invention will readily occur to those skilled in the art, and therefore, do not limit the scope of the present invention.

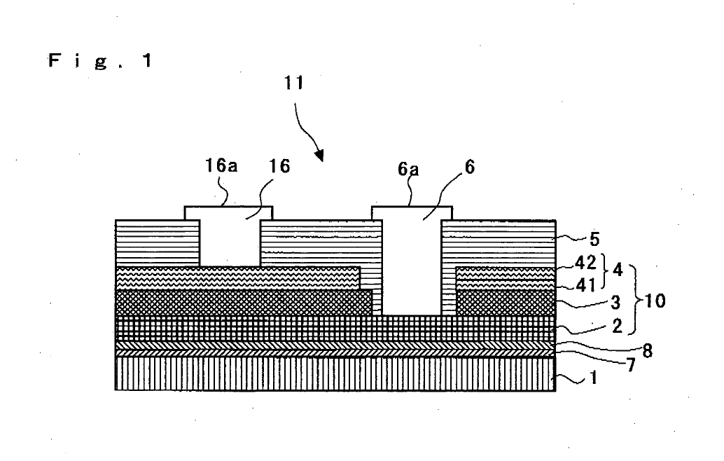

FIG. 1 is diagram showing a structure of a part of a semiconductor element having a thin-film capacitor according to the present invention. As shown in FIG. 1, a thin-film capacitor 10 has a silicon (Si) substrate 1. The thin-film capacitor 10 is formed on the substrate 1 via an insulating film 7 made of SiO₂, and an adhesive layer 8 made of TiO₂. The thin-film capacitor 10 includes a lower electrode layer 2 such as a Pt electrode, a ferroelectric or high dielectric constant layer 3 such as a (Ba₂ Sr) TiO₃ layer, and an upper electrode layer 4 such as IrO₂ as an electrode having a compressive stress, in order from the side of the substrate. The upper surface of the thin-film capacitor 10 is protected by a protective layer 5 formed from an insulation resin such as epoxy resin. Contact holes 6 and 16 are formed on the protective layer 5. A conductive metal such as copper (Cu) is filled in these contact holes. The top surfaces of the contact holes 6 and 16 have electrode pads 6a and 16a, respectively. External terminals such as solder bumps (not shown) can be fitted to the electrode pads 6a and 16a, respectively. An optional electronic element such as a semiconductor element 11, for example, an LSI chip, can be mounted on the external terminal. Although not shown, the thin-film capacitor can have one or more additional layers at an optional position, if necessary.

The upper electrode 4 of the thin-film capacitor 10 according to the present invention has a residual compressive stress. This residual compressive stress can be added to the ferroelectric layer 3 that is laminated consistently.

According to the thin-film capacitor 10 that is formed with the thin-film ferroelectric layer 3 such as a perovskite oxide, the ferroelectric layer 3 has a residual tensile stress because the ferroelectric layer 3 is cooled down after the film is formed at a high temperature of 400° C. to 700° C. When the film is formed at a higher temperature, a tensile stress of a plus few 10⁹ dyne/cm² remains, and is added to the ferroelectric layer 3, thereby decreasing the dielectric constant. In order to decrease the stress due to thermal expansion inconsistency, it is considered suitable to use a substrate of SrTiO₃ and MgO having a thermal expansion coefficient near that of the ferroelectric layer 3 like a perovskite oxide. However, these substrates are expensive, and severely limit selectivity of a substrate. Further, internal stresses or the like need to be adjusted in the manufacturing process.

According to the thin-film capacitor 10 of the present invention, a film-forming condition is changed at the time of forming a conductive oxide film as the upper electrode 4 on the ferroelectric layer 3. With this arrangement, an internal stress can remain in the upper electrode 4. Further, a compressive or tensile stress can be added to the ferroelectric layer 3 on the silicon substrate based on a residual internal stress in the upper electrode 4. In this case, in order to improve the dielectric constant of the ferroelectric layer 3, the internal stress is held in the upper electrode 4 so as to add the compressive stress to the ferroelectric layer 3. With this arrangement, while the dielectric constant and the charge capacity are substantially decreased due to a residual tensile stress in the ferroelectric layer 3 when it is filmed, the residual internal stress in the upper electrode 4 can restrict a reduction in the dielectric characteristics.

The residual compressive stress can be identified by measuring a change of a curvature by applying a laser beam to the upper electrode before and after forming the film. The internal residual stress can be also obtained as follows. Based on the X-ray diffraction method (XRD), an χ angle is continuously changed while rotating a sample, and the detector is rotated by optically relating the position of the detector to 2θ. An X ray emitted from the surface of the diffracted sample is detected, and a distance between the grating surfaces of the crystal lattice is measured. From a relational diagram of 2θ-sin²_{χ} obtained at this time, a slope is obtained based on the method of least squares. A coefficient is multiplied based on a difference from an intrinsic value, thereby obtaining a residual internal stress.

For example, when an IrO₂ film is formed as the upper electrode 4 on the silicon substrate 1 according to the high-frequency sputtering method (RF method), a residual internal stress can be adjusted by controlling a size of the high-frequency output and a thickness of the formed film.

| | Depositing condition | | | | |
|---|---|---|---|---|---|
| | RF | | | | |
| | output | Pressure | Ar/O² | Thickness | Stress |
| Experiment No. | (W) | (Pa) | Ratio | (nm) | (dyne/cm²) |
| Experiment 1 | 80 | 0.2 | 3/7 | 100 | −51.2 × 10⁹ |
| Experiment 2 | 100 | 0.2 | 3/7 | 100 | −36.2 × 10⁹ |
| Experiment 3 | 100 | 0.2 | 3/7 | 25 | −7.4 × 10⁹ |

As shown in Table 1, it is clear that the residual internal stress changes greatly based on the depositing condition at the manufacturing time. When the output (RF power) of a high frequency in the high-frequency sputtering method (RF method) is changed from 100 W to 80 W, the residual compressive stress of the IrO2 film can be increased from −36.2×10⁹ dyne/cm² to −51.2×10⁹ dyne/cm². When the film thickness of the IrO₂ layer 4 is decreased from 100 nm to 50 nm, the residual compressive stress can be decreased from −36.2×10⁹ dyne/cm² to −7.4×10⁹ dyne/cm².

According to the thin-film capacitor 10 of the present invention, the residual compressive stress of the upper electrode 4 is set to within a range from −10⁹ to −6×10¹⁰ dyne/cm². In this case, the “−” sign represents the compressive stress. When the film of the upper electrode 4 is formed on the ferroelectric layer 3 by sputtering or vacuum deposition, and also when the film is thermally treated, there is a consistency between the ferroelectric layer 3 and the upper electrode 4. The upper electrode 4 binds the ferroelectric layer 3, and adds a compressive stress to the ferroelectric layer 3. When the compressive stress is added to the ferroelectric layer 3, a reduction of the dielectric constant of the ferroelectric substance can be prevented, and the dielectric characteristics of polarization or the like per unit area can be improved.

When the residual compressive stress of the upper electrode 4 is less than −10⁹ dyne/cm², a large compressive stress cannot be added to the ferroelectric layer 3, and therefore, dielectric characteristics cannot be improved. When the residual compressive stress exceeds −6×10¹⁰ dyne/cm², there is a risk that the upper electrode 4 is warped, and consistency of the ferroelectric layer 3 is destroyed to peel off the upper electrode 4. When a metal upper electrode such as Au is additionally provided on the upper electrode 4 as described later, there is risk that the upper electrode is peeled off when the residual compressive stress exceeds −6×10 dyne/cm². Even when the upper electrode is not peeled off, when consistency is destroyed, a gap is generated. When a voltage is applied to the thin-film capacitor 10, a leak current flows in some cases.

As explained above, when IrO₂ or the like having a residual compressive stress is used for the upper electrode 4, the tensile stress that is generated due to a large difference between the thermal expansion coefficient of the silicon substrate 1 and that of the ferroelectric substance 4 like BST and that remains after the ferroelectric substance 4 is cooled down from the high film-forming temperature of 400° C. to 700° C. can be compensated for. Consequently, a reduction of the dielectric constant of the ferroelectric substance 4 can be prevented.

According to the thin-film capacitor 10 of the present invention, the substrate 1 is preferably formed from an electrically insulating material. While the insulating material includes glass such as SiO₂ and TiO₂, a semiconductor material such as Si and SiC, and a resin material such as epoxy resin and phenol resin, the material is not limited to these. A material of the substrate can be selected from the viewpoint of consistency of the thermal expansion coefficient with the ferroelectric layer, and can correspond to various semiconductor devices 11.

The thin-film capacitor 10 can further have one or two or more insulating layers 7 laminated on the substrate 1. The insulating layer 7 is preferably formed from at least one kind of insulating material selected from an oxide, a nitride, or an oxynitride of metal, a metal oxide of a high dielectric constant, and an organic resin, or a compound or a mixture of these materials. The insulating layer can be used in the form of a single layer or in the form of a multilayer structure of two or more layers. The insulating material can be selected from the easiness of an epitaxial growth corresponding to the selected semiconductor material or wafer.

Further, the semiconductor device 11 can have the adhesive layer 8 that increases the coupling strength between the substrate 1 and the thin-film capacitor 10. The adhesive layer 8 is formed from at least one kind of material selected from a metal made of Pt, Ir, Zr, Ti, TiOₓ (where x represents 2, and the composition may not be a stoichiometric composition, which are also applied to the following substances), IrOₓ, PtOₓ, ZrOₓ, TiN, TiAlN, TaN, TaSiN, an alloy of these metals, a metal oxide, and a metal nitride. The adhesive layer 8 can be used in the form of a single layer, or can be used in a multilayer structure of two or more layers. Particularly, TiOₓ is preferable for the adhesive layer 8. A thin film made of TiOₓ can increase adhesiveness of both the lower electrode 2 made of Pt and the SiO₂ thin film.

Metal of Pt, Pd, Ir, Ru, and the like and a conductive oxide of PtOₓ (where x represents 2, and the composition may not be a stoichiometric composition, which are also applied to the following substances), IrOₓ, RuOₓ, and the like can be used for the material of the lower electrode 2 of the thin-film capacitor 10. This is because the above material is excellent in oxidation resistance in a high-temperature environment and because a satisfactory crystal orientation control is possible at the time of forming the dielectric layer. According to the present embodiment, Pt is preferably used for the lower electrode. Since Pt has high conductivity and is chemically stable, it is suitable for the lower electrode layer of the ferroelectric thin film. One substance selected from a conductive oxide, their compound, and a mixture of PtOₓ, IrOₓ, and RuOₓ can be used for the lower electrode.

The ferroelectric layer 3 of the thin-film capacitor 10 according to the present invention uses a perovskite oxide having a constitutional formula ABO₃ (where A represents at least one cation having a positive charge of 1 to 3, and B represents a metal of the IVB group (Ti, Zr, or Hf)), the VB group (V, Nb, or Ta), the VIB group (Cr, Mo, or W), the VIIB group (Mn or Re), or the IB group (Cu, Ag, or Au) in the periodic table. Specifically, the ferroelectric layer 3 can be a layer including any one of perovskite oxides selected from a group of (Ba, Sr) TiO₃ (BST), SrTio₃ (ST), BaTiO₃, Ba (Zr,Ti) O₃, Ba (Ti, Sn) O₃, Pb (Zr, Ti) O₃ (PZT), and (Pb, La) (Zr, Ti) O₃ (PLZT), or a layer made of a mixture that includes two or more of these dielectric materials, such as Pb (Mn, Nb) O₃—PbTiO₃ (PMN-PT), and Pb (Ni, Nb) O3-PbTiO₃. The perovskite oxides include a crystal structure, and these are not limited to a stoichiometric composition.

The ferroelectric layer 3 of the thin-film capacitor 10 according to the present invention uses a pyrochlore oxide having a constitutional formula A₂B₂O_{z}, (where A represents at least one cation having a positive charge of 1 to 3, B represents a metal of the IVB group, the VB group, the VIB group, the VIIB group, or the IB group in the periodic table that constitutes an acid oxide, and z represents 6 or 7). Specifically, the ferroelectric layer 3 can be a layer including any one of pyrochlore oxides selected from a group of Ba₂TiO_{z}, Sr₂TiO_{z}, (Ba,Sr)₂ Ti₂O_{z}, Bi₂Ti₂O, (Sr, Bi)₂ Ta₂O_{z}, (Sr, Bi)₂ Nb₂O_{z}, (Sr, Bi)₂ (Ta, Nb)₂ O_{z}, Pb (Zr, Ti)₂ O_{z}, (Pb, La)₂, and (Zr, Ti)₂ O_{z}, or a layer made of a mixture including two or more of these dielectric materials.

The ferroelectric materials of the ferroelectric layer 3 can be selected from the viewpoint of consistency of a lattice constant and a thermal expansion coefficient according to a type of a substrate on which the thin-film capacitor is formed. The thin-film capacitor according to the present invention can be used for the semiconductor device 11.

The upper electrode 4 can be formed by plural layers. A first conductive layer (first conductive layer) 41 is provided as one of the upper electrodes 4 adjacent to the ferroelectric layer 3. The first conductive layer (first conductive layer) 41 is made of a conductive oxide material, and has a thickness equal to or smaller than 500 nm, an internal residual compressive stress of 10⁹ to 6×10¹⁰ dyne/cm², and a surface resistance equal to or smaller than 10⁴ Ω/□. The first conductive layer 41 is formed by at least one conductive oxide selected from a group of PtOₓ, IrOₓ, RuOₓ, RhOₓ, OsOₓ, ReO_{y}, SrRuO₃, and LaNiO₃ (where x represents about 2, and y represents about 3, and these are not limited to a stoichiometric composition). An electric field can be directly applied to the ferroelectric layer 3. Particularly, IrOₓ is most preferable for the first conductive layer 41, because the IrOₓ has high conductivity and has high adhesiveness with the lower ferroelectric layer 3.

The first conductive layer 41 has a film thickness equal to or smaller than 500 nm. When the film thickness exceeds 500 nm, the electric field to the ferroelectric layer 3 decreases, and a polarization response at a low voltage decreases. Preferably, the film thickness is 100 nm or above. When the film thickness is less than 100 nm, a leak current occurs easily, and a high electric field cannot be applied. The thickness is measured by visual observation with an electronic microscope (SEM).

The surface resistance is set equal to or smaller than 10⁴ Ω/□. This surface resistance can be adjusted by adjusting a composition ratio between metal and oxide, and electric resistance increases when the composition is deviated from the stoichiometric composition. When the polarization frequency increases by applying the electric field, the surface resistance becomes large, and dielectric loss becomes large. Therefore, when the surface resistance in the direct current decreases, the dielectric loss in the alternating current can be decreased. Consequently, according to the present invention, when the surface resistance is set equal to or smaller than 10⁴ Ω/□, the dielectric loss can be set to a size having no practical problem. Preferably, the surface resistance is set equal to or more than 10¹ Ω/□. When the surface resistance is set equal to or smaller than 10¹ Ω/□, a leak current from the side surface increases.

The surface resistance is measured according to a three-terminal method for measuring a leak current by applying a voltage to between electrode terminals in vacuum and in the atmosphere, using a measuring electrode which is manufactured by depositing a sample surface and the back surface.

An internal compressive stress of the first conductive layer (first conductive layer) 41 is set within a range from 10⁹ to 6×10¹⁰ dyne/cm². When the internal compressive stress is less than 10⁹ dyne/cm², a large compressive stress cannot be added to the ferroelectric layer 3. Therefore, the dielectric characteristics cannot be improved. When the internal compressive stress exceeds −6×10¹⁰ dyne/cm², the upper electrode 4 is warped, and consistency of the ferroelectric layer 3 is destroyed to peel off the upper electrode 4. The internal stress is measured according to the X-ray diffraction method (XRD).

As one of the upper electrodes 4 adjacent to the ferroelectric layer 3, a second conductive layer (second conductive layer) 42 adjacent to the first conductive layer (first conductive layer) 41 is made of a metal, which has a thickness within a range from 50 to 500 nm, an internal tensile stress of equal to or less than 6×10⁹ dyne/cm², and a surface resistance equal to or smaller than 10 Ω/□.

The second conductive layer includes at least one of metals selected from a group of Pt, Pd, Ir, Ru, Rh, Re, Os, Au, Ag, and Cu, as a main component. These are noble metals that are not easily oxidized. A metal to be used forms an oxide having conductivity even when the metal is oxidized. Based on this, even when the second conductive layer is exposed to a high temperature in the manufacturing stage or even when the second conductive layer is used for a long time, there is little trouble in the operation of the thin-film capacitor 10.

The second conductive layer 42 has a thickness within a range from 50 to 500 nm. When the thickness is less than 50 nm, it is difficult to obtain high adhesiveness. When the thickness exceeds 500 nm, the film-forming time becomes long, and productivity decreases.

The second conductive layer 42 has a surface resistance equal to or smaller than 10 Ω/□. When the surface resistance is small, power consumption can be decreased. Preferably, the surface resistance is equal to or above 10⁻³ Ω/□. When the surface resistance is less than 10 Ω/□, a leak current increases.

The second conductive layer 42 has an internal tensile stress equal to or less than 6×10⁹ dyne/cm². The internal tensile stress remains in the second conductive layer 42 on the first conductive layer 41 for the following reason. Because the internal compressive stress remains in the first conductive layer 41 to add a compressive stress to the ferroelectric layer 3, when the internal compressive stress also remains in the second conductive layer 42, there is risk that the upper electrode 4 is peeled off from the ferroelectric layer 3. Therefore, in order to prevent this risk and to mitigate the total residual stress in the upper electrode 4, the opposite tensile stress is kept remained. When the residual tensile stress exceeds 6×10⁹ dyne/cm², there is a risk that the second conductive layer 42 is peeled off from the first conductive layer 41.

A semiconductor device 11 can be manufactured by including the thin-film capacitor according to the present invention.

In the process of forming the thin-film capacitor 10 on the semiconductor substrate 1, the semiconductor layer 1, the insulating layer 7, the adhesive layer 8, the lower electrode layer 3, the ferroelectric layer 3, and the upper electrode layer 4 having the first conductive layer 41 and the second conductive layer 42, are sequentially formed, thereby manufacturing the thin-film capacitor 10. These insulating layers can be formed by, for example, the vacuum evaporation method, the sputtering method, the thermal oxidation method, the chemical vapor deposition (CVD) method, solution methods such as the sol-gel method.

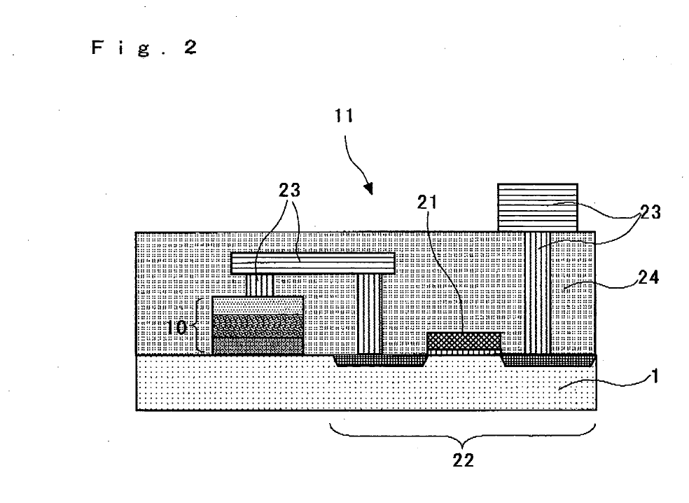

FIG. 2 is a cross-sectional diagram of a semiconductor device including the thin-film capacitor according to the present invention. As shown in FIG. 2, the thin-film capacitor 10 according to the present invention is formed on a part of the surface of the silicon substrate 1, thereby forming a drawing electrode 23. On the other hand, a transistor 22 including a gate, a source, and drain including a gate electrode 21 is formed in another area of the silicon substrate 1. The semiconductor device 11, as the DRAM and the FRAM, including the thin-film capacitor according to the present invention can be used by suitably connecting the transistor and the capacitor.

The thin-film capacitor 10 can be also used as a decoupling capacitor. The decoupling capacitor is formed as follows. For example, an electrode layer and a dielectric layer are laminated on a silicon substrate. An opening is selectively formed on the electrode layer, and many drawing electrodes are formed that are connected to the electrode layer in the thickness direction through the insulation layer. A solder bump is formed on the drawing electrodes, and a surface mounting is made possible. The ferroelectric layer of the thin-film capacitor according to the present invention can have a high dielectric constant. A charge capacity that is formed in the same thickness and on the same area can be increased. Because the ferroelectric layer has a sufficient capacity and the film thickness can be decreased correspondingly, low inductance and low resistance can be obtained.

The thin-film capacitor 10 can also have a variable characteristic of a high-frequency passage characteristic based on the applied voltage, and can be used as a compact new high-frequency filtering device having a wide frequency variable range. The thin-film capacitor 10 can have a refraction index variable based on the applied voltage. As a result, the thin-film capacitor 10 can be used as an optical filter element. Further, the thin-film capacitor 10 can be used for various devices such as a surface elastic wave element, an optical waveguide, an optical storage, a space optical modulator, and a piezoelectric actuator.

### EMBODIMENTS

The present invention will be explained in further detail below based on several embodiments.

### First Embodiment and First Comparative Example

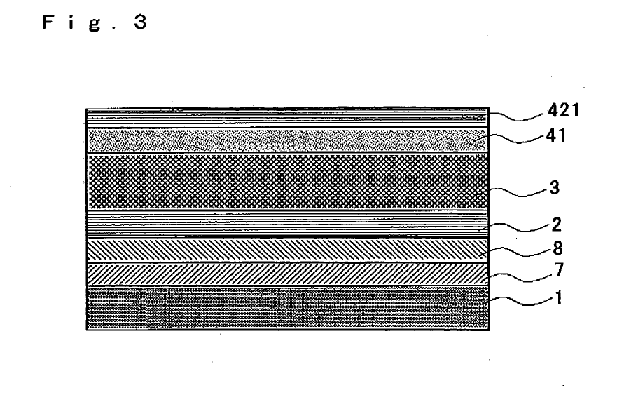

FIG. 3 is a diagram showing a structure of a thin-film capacitor according to a first embodiment of the present invention.

First, the adhesive layer 8 made of TiO₂ having a film thickness of 20 nm is formed by the sputtering method via the insulating film 7 made of SiO₂ that is obtained by thermal oxidation on the silicon substrate 1. Next, the lower electrode 2 made of Pt having a film thickness of 100 nm is formed by the sputtering method at a film forming temperature of 400° C. The ferroelectric layer 3 made of a high dielectric material Ba_{0.7}Sr_{0.3}TiO₃ (BST) having a film thickness of 100 nm is formed by the sputtering method at a film forming temperature of 500° C. As a result, a Si/SiO₂/TiO₂/Pt/BST/Pt structure is obtained.

Further, a first conductive layer is deposited on the ferroelectric layer 3, as an electrode by an IrO₂ conductive layer 41, with a thickness of 50 nm and in a residual compressive stress of −3.9×10¹⁰ dyne/cm² and a surface resistance of less than 10⁴ Ω/□. Finally, a second conductive layer is deposited on the first conductive layer, and a Pt layer 421 is provided to have a thickness of 100 nm and in a residual tensile stress of less than 6×10⁹ dyne/cm² and a sheet resistance of less than 10 Ω/□, thereby manufacturing a thin-film capacitor having a layer structure of Si1/SiO₂7/TiO₂8/Pt2/BST3/IrO₂41/Au422.

As a first comparative example, a thin-film capacitor having a structure of Si/SiO₂/TiO₂/Pt/BST/Pt is manufactured. A thickness of an upper electrode Pt layer is set equal to 100 nm of the lower electrode layer.

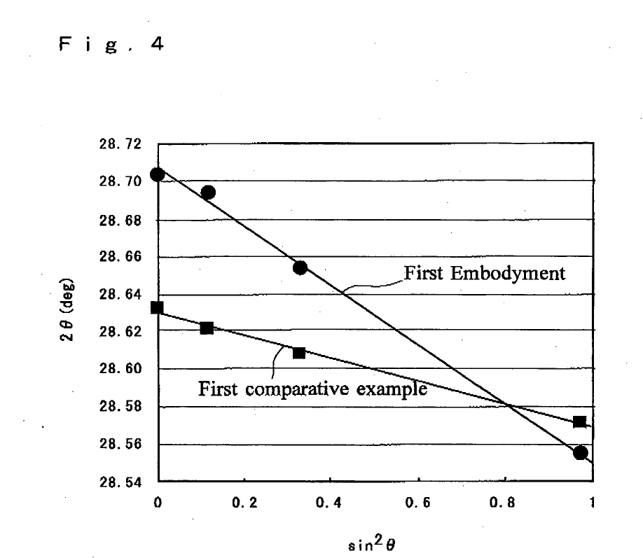

The internal residual stress of the ferroelectric layer according to the first embodiment and the internal residual stress of the ferroelectric layer according to the comparative example are measured by transmitting X-rays through the upper electrodes according to the XRD method. FIG. 4 is a graph showing a result of measuring a relationship between 2θ and sin²_{χ} of the thin-film capacitor according to the present invention based on the XRD measurement.

As shown in FIG. 4, it is clear that the residual tensile stress of the ferroelectric layer according to the first embodiment is smaller than the residual tensile stress of the ferroelectric layer according to the first comparative example. The residual tensile stress of the ferroelectric layer according to the first embodiment is 8.9×10⁸ dyne/cm², and the residual tensile stress of the ferroelectric layer according to the first comparative example is 2.3×10⁹ dyne/cm².

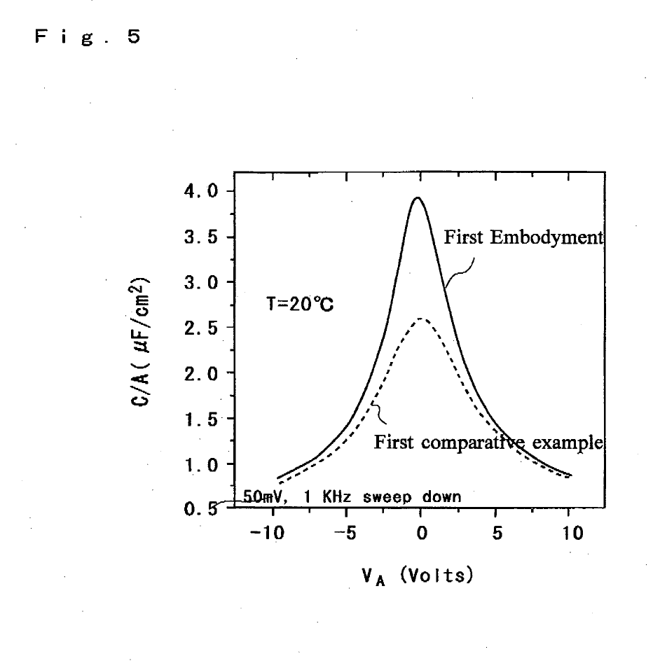

FIG. 5 is a graph showing a C-V curve of the thin-film capacitor according to the first embodiment of the present invention. According to the thin-film capacitor of the first embodiment, the electric charge (C/A) increases by 38% from that of the thin-film capacitor according to the first comparative example. It is clear from this that the charge capacity of the thin-film capacitor can be increased by providing a layer having a compressive stress of the upper electrode.

### Second Embodiment

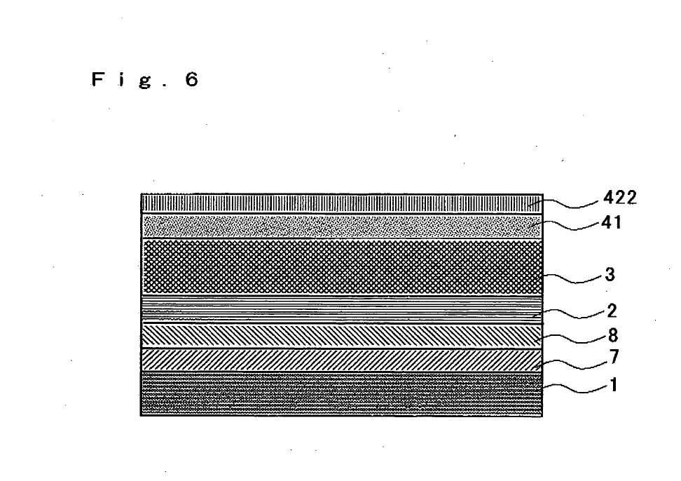

FIG. 6 is a diagram showing a structure of a thin-film capacitor according to another embedment of the present invention.

In a second embodiment, TiO₂ of 20 nm is deposited on a thermally oxidized silicon substrate by sputtering from a TiO₂ target. Next, Pt of 100 nm is deposited by sputtering at 400° C. Thereafter, a high dielectric material Ba_{0.7}Sr_{0.3} TiO₃ (BST) is deposited by 100 nm by a RF sputtering method at 500° C. Next, the IrO₂ conductive layer 41 having a conductive compressive tension 75 nm is deposited in a residual compressive stress of −5×10¹⁰ dyne/cm² and a sheet resistance of less than 10⁴ Ω/□. Finally, an Au layer 422 is provided to have a thickness of 500 nm in a residual tensile force less than 6×10⁹ dyne/cm² and a sheet resistance 10 Ω/□, thereby manufacturing a thin-film capacitor having a layer structure of Si1/SiO₂7/TiO₂8/Pt2/BST3/IrO₂41/Au422.

The thin-film capacitor having this structure can have an increased dielectric constant and a large charge capacity, by providing a conductive layer having a residual compressive stress as an electrode adjacent to the ferroelectric layer, like the capacitor element having the structure in the first embodiment.

As explained above, when the compressive stress remains in the conductive electrode adjacent to the ferroelectric layer of the capacitor element according to the present invention, the dielectric constant can be increased and the charge capacity can be increased.

Embodiments of the present invention have been explained above, and the characteristics listed below, for example, can be abstracted from the invention.

What is claimed is:

1. A thin-film capacitor having a lower electrode, a ferroelectric layer, and an upper electrode, wherein
the thin-film capacitor has the upper electrode that adds a compressive stress to the ferroelectric layer.

2. A thin-film capacitor according to claim 1, wherein
a residual compressive stress of the upper electrode is within a range from 10⁹ to 6×10¹⁰ dyne/cm².

3. A thin-film capacitor according to claim 1, wherein
the upper electrode has a plurality of layers, and a first conductive layer that is adjacent to the ferroelectric layer (first conductive layer) is made of a conductive oxide material, and has a thickness equal to or smaller than 500 nm, an internal residual compressive stress of 10⁹ to 6×10¹⁰ dyne/cm², and a surface resistance equal to or smaller than 10⁴ Ω/□.

4. A thin-film capacitor according to claim 3, wherein
a second conductive layer that is adjacent to the first conductive layer (second conductive layer) is made of a metal, and has a thickness within a range from 50 to 500 nm, a residual tensile stress of 6×10⁹ dyne/cm, and a surface resistance equal to or smaller than 10 Ω/□.

5. A thin-film capacitor according to claim 4, wherein
the ferroelectric layer is formed by an oxide having a perovskite structure.

6. A thin-film capacitor according to claim 5, wherein
the oxide having the perovskite structure is at least one of oxides selected from a group of (Ba, Sr) TiO₃ (BST), SrTiO₃ (ST), BaTiO₃, Ba(Zr, Ti)O₃, Ba (Ti, Sn)O₃, Pb (Zr, Ti)O₃ (PZT), (Pb, La) (Zr, Ti)O₃ (PLZT).

7. A thin-film capacitor according to claim 4, wherein
the ferroelectric layer is formed by an oxide having a pyrochlore structure.

8. A thin-film capacitor according to claim 7, wherein
the oxide having a pyrochlore structure according is at least one of oxides selected from a group of Ba₂TiO_{z}, Sr₂TiO_{z}, (Ba,Sr)₂ Ti₂O_{z}, Bi₂Ti₂O, (Sr, Bi)₂ Ta₂O_{z}, (Sr, Bi)₂ Nb₂O_{z}, (Sr, Bi)₂ (Ta, Nb)₂ O_{z}, Pb (Zr, Ti)₂ O_{z}, (Pb, La)₂, and (Zr, Ti)₂ O_{z}, (where z represents 6 or 7, and these are not limited to a chemical stoichiometric composition).

9. A thin-film capacitor according to claim 4, wherein
the first conductive layer is at least one of metal oxides selected from a group of PtOₓ, IrOₓ, RuOₓ, RhOₓ, OsOₓ, ReO_{y}, SrRuO₃, and LaNiO₃ (where x represents about 2, and y represents about 3, and these are not limited to a stoichiometric composition).

10. A thin-film capacitor according to claim 9, wherein
the second conductive layer is at least one of metals selected from a group of Pt, Pd, Ir, Ru, Rh, Re, Os, Au, Ag, and Cu, as a main component.

11. A thin-film capacitor according to claim 10, wherein
the lower electrode is made of at least one of materials selected from a group of Pt, Ir, Ru, PtO₂, IrO₂, and RuO₂.

12. A thin-film capacitor according to claim 11, wherein
the thin-film capacitor has an adhesive layer made of at least one material selected from a group of a metal, a metal oxide, a metal nitride, and a metal oxynitride, between the substrate and the lower electrode.

13. A thin-film capacitor according to claim 12, wherein
the thin-film capacitor has an adhesive layer made of at least one material selected from a group of Pt, Ir, Zr, Ti, TiOx, IrOx, PtOx, ZrOx, TiN, TiAIN. TaN, and TaSiN, between the substrate and the lower electrode.

14. A semiconductor device having a thin-film capacitor formed on a semiconductor substrate, wherein
the thin-film capacitor has a lower electrode, a ferroelectric layer, and an upper layer, and
includes the upper electrode that adds a compressive stress to the ferroelectric layer.

15. A semiconductor device according to claim 14, wherein
the semiconductor device is a ferroelectric random access memory (FRAM), and the thin-film capacitor is used as a memory cell that stores a charge.

16. A semiconductor device according to claim 15, wherein
the semiconductor device is a dynamic random access memory (DRAM), and the thin-film capacitor is used as a memory cell that stores a charge.

17. A semiconductor device according to claim 15, wherein
the semiconductor device is a decoupling element, and the thin-film capacitor is used as a common source of charge.

18. A semiconductor device according to claim 15, wherein
the semiconductor device is a high-frequency filter element, and the thin-film capacitor is used as a filter of which resonance characteristics change based on an applied voltage.

19. A semiconductor device according to claim 15, wherein
the semiconductor device is an optical filter element, and the thin-film capacitor is used as a filter of which refraction index changes based on an applied voltage.
